(19) United States
(12) Patent Application Publication
(10) Pub. No.: US 2006/0216953 A1
(43) Pub. Date: Sep. 28, 2006

(54) Method of forming film and film forming apparatus

(76) Inventors: Shigeru Nakajima, Tokyo (JP); Dong-Kyun Choi, Tokyo-To (JP); Tomonori Fujiwara, Tokyo-To (JP); Hiroaki Ikegawa, Tokyo-To (JP); Genji Nakamura, Tokyo-To (JP)

Correspondence Address: SMITH, GAMBRELL & RUSSELL, 1850 M STREET, N.W., SUITE 800, WASHINGTON, DC, 20036, US

(21) Appl. No.: 10/552,468

(22) PCT Filed: Apr. 8, 2004
(86) PCT No.: PCT/JP04/05082

§ 371 Date: Oct. 7, 2005

(30) Foreign Application Priority Data
Apr. 8, 2003 (JP) 2003-104437

(51) Int. Cl. H01L 21/31; H01L 21/469

(52) U.S. Cl. 438/785

(57) ABSTRACT

The object of the present invention is to increase the crystallization temperature of a hafnium compound film which can be effectively used as a high dielectric constant film of a gate oxide film of a MOSFET, for example. A hafnium silicate film is deposited on a substrate by reacting a vapor of a hafnium organic compound with a monosilane gas or a disilane gas in a reaction vessel in a heated vacuum atmosphere. Due to the crystallization restraining effect of silicon, the thus obtained film has a higher crystallization temperature. In another embodiment of the present invention, an oxygen-containing hafnium compound film is annealed in a heated ammonia gas atmosphere. The annealing also increase the crystallization temperature of the oxygen-containing hafnium compound film.

### FIELD OF THE INVENTION

The present invention relates to a method and an apparatus for forming a high dielectric constant film which can be suitably used as a gate oxide film of a MOSFET (Metal Oxide Semiconductor Field Effect Transistor), a capacitive element of a memory cell, and so on.

### BACKGROUND ART

A semiconductor device must satisfy various strict requirements. For example, a gate oxide film of a MOSFET must have a small leak current, a large withstand voltage, and high reliability. In addition, there has been recently a demand for reduced capacity to further improve the working speed. By reducing the thickness of the film, the capacity can be reduced. However, when the thickness of a silicon oxide (SiO₂) film, which has been conventionally used as a gate oxide film, is reduced, the leak current is undesirably increased to a considerable degree.

Thus, a material having a higher dielectric constant (relative dielectric constant) than that of silicon oxide has been employed recently. The high dielectric constant film is advantageous in that it achieves a small electric film thickness even if the physical film thickness (actual film thickness) thereof is large. In addition, a large physical film thickness achieves a reduced leak current. The electric film thickness (T₀) of a film of a certain material is calculated by converting the physical film thickness of a film of a certain material into an equivalent thickness of a silicon oxide film on the basis of the capacity, and can be given by the following expression:
T₀=(ε₀/ε₁)×T₁
where T₁ is the physical film thickness of the film; ε₁ is the dielectric constant of the material forming the film; and ε₀ is the dielectric constant of the silicon oxide film.

Recently, a hafnium oxide film (HfO₂ film) has drawn attention as a high dielectric constant film. The dielectric constant of a hafnium oxide film is significantly higher than that of a silicon oxide film, the former being about 40, and the latter being about 4.

JP2002-343790A discloses that: a hafnium oxide film is deposited on a substrate by alternately irradiating a raw material of an organic metal compound such as tetra-tertiary-butoxy hafnium, and oxygen radical or nitrogen radical; and that a hafnium silicate film is deposited on a substrate by alternately irradiating a mixture of tetra-tertiary-butoxy hafnium and tetra-methyl-silane, and oxygen radical.

JP2002-246388A discloses that a hafnium oxide film is deposited by a low-pressure CVD process that reacts an organic compound of hafnium with an oxidizing gas such as oxygen or ozone, and suggests that a liquid organic compound including hafnium and silicon is used as a raw material.

In manufacturing a MOSFET, a gate oxide film is deposited on a substrate, a polysilicon film is deposited on the gate oxide film and boron or phosphor is implanted in the polysilicon film to form a gate electrode, and annealing treatment is performed at about 1,000° C. for a short period of time. However, when a hafnium oxide film is exposed to a high temperature even for a short period, a part thereof is crystallized, which results in leakage of current through grain boundaries. Thus, the leakage current of the gate oxide film is disadvantageously increased.

If a hafnium silicate film is deposited by using tetra-tertiary-butoxy hafnium mixed with an organic compound such as tetra-methyl-silane, the crystallization temperature of the film may be increased due to the presence of silicon. However, if an organic material is used as a silicon source, an amount of carbon contained in a hafnium silicate film increases. It causes disadvantages such as an increase of the fixed charge, and deterioration in reliability and the withstand voltage of the device. In addition, since the silicon content in the film depends on the mixing ratio of the liquid organic compound, the mixing ratio may be incompatible with other process conditions.

### SUMMARY OF THE INVENTION

The present invention has been made in view of the foregoing context. The principal object of the present invention is to provide a method and an apparatus for forming a hafnium compound film having a high crystallization temperature.

The film forming method according to the first aspect of the present invention is characterized by depositing a hafnium silicate film on a substrate by reacting a hafnium organic compound and a silane-series gas with each other in a reaction vessel. A CVD method may be used for the deposition. In this case, a heated vacuum atmosphere is established in the interior of the reaction vessel, and the hafnium organic compound in a vapor state is supplied into the reaction vessel. Silane-series gases expressed as SiₙH₍₂ₙ₊₂₎ may be used. Preferably, the silane-series gas is monosilane (SiH₄) gas or disilane (Si₂H₆) gas. It is possible to use both monosilane gas and disilane gas together.

In the hafnium silicate film obtained by the present invention, silicon contained in the hafnium silicate film suppresses the crystallization of the film. Thus, when the hafnium silicate film is heated, crystallization of the film occurs at a higher temperature. Therefore, in a case where a hafnium silicate film deposited on a substrate is exposed to a high temperature, for example, in a case where a polysilicon film formed after the deposition of the hafnium silicate film to overlie the same is annealed, the hafnium silicate film is unlikely to be crystallized, so that the leak current of the hafnium silicate film can be minimized. Further, a silane-series gas such as monosilane gas and disilane gas is used as a source of silicon, the silicon content can be easily, optionally adjusted by adjusting the supply amount of the gas.

The hafnium silicate film obtained by the present invention can be suitably applied to a gate oxide film of a MOSFET. However, not limited thereto, the film can be applied to other elements such as a capacitive element of a memory cell.

The film forming method according to the second aspect of the present invention is characterized by annealing a hafnium compound film in an atmosphere of a compound gas of nitrogen and hydrogen such as ammonia gas, after depositing the hafnium compound film including hafnium and oxygen on a substrate. The annealing raises the crystallization temperature of the oxygen-containing hafnium compound film. Alternatively, after the oxygen-containing hafnium compound film is annealed, a silicon nitride film may be deposited thereon. Since the silicon nitride film is also a high dielectric constant film, a high dielectric constant film of a two-layered structure including the hafnium compound film and the silicon oxide film can be formed. The oxygen-containing hafnium compound film according to the second aspect of the present invention is preferably the hafnium silicate film obtained by the film-forming method according to the first aspect of the present invention. However, not limited thereto, the oxygen-containing hafnium compound film may be such that it does not contain silicon. In this case as well, the crystallization temperature of the oxygen-containing hafnium compound film without containing silicon rises, by annealing the film in an atmosphere of a compound gas of nitrogen and hydrogen.

According to the present invention, a hafnium compound film containing silicon (hafnium silicate film) can be obtained. Due to the anti-crystallization effect of silicon, the hafnium compound film having a high crystallization temperature can be obtained. Thus, when the hafnium compound film is exposed to a high temperature atmosphere in a succeeding process, for example, crystallization of the film can be restrained. Accordingly, the leak current can be suppressed when a voltage is applied thereto. Further, a silane-series gas such as monosilane gas and disilane gas is used as a source of silicon, the silicon content can be easily, optionally adjusted by adjusting a supply amount of the gas.

In addition, according to the present invention, since a hafnium compound film is annealed in a heated atmosphere by using ammonia gas, a hafnium compound film having a high crystallization temperature can be obtained, which will be clearly seen from the examples, which will be descried later.

Furthermore, the present invention provides a film-forming apparatus that can be suitably used to perform the foregoing film-forming method. The apparatus for depositing a film includes: a reaction vessel into which a substrate is loaded; a heating mechanism that heats an atmosphere in the reaction vessel; a first gas-supplying means for supplying a vapor of a hafnium organic compound into the reaction vessel; a second gas-supplying means for supplying a silane-series gas into the reaction vessel; and a controller that controls the heating mechanism and the first and second gas-supplying means to deposit a hafnium silicate film on a substrate by reacting the hafnium organic compound and the silane-series gas in the reaction vessel.

### BRIEF DESCRIPTION OF THE DRAWINGS

FIG. 1 is a vertical cross-sectional view of a film forming apparatus in one embodiment according to the present invention;

FIG. 2 shows schematic illustrations for explaining a series of process steps of a film forming method according to the present invention;

FIG. 3 shows schematic illustrations for explaining a series of process steps of another film forming method according to the present invention;

FIG. 4 is a graph showing results of x-ray diffraction analysis of hafnium silicate films, which were formed by using a hafnium organic compound and disilane gas and then heated at respective temperatures;

FIG. 5 is a graph showing results of x-ray diffraction analysis of hafnium silicate films, which were formed by using a hafnium organic compound and monosilane gas and then heated at respective temperatures;

FIG. 6 is a graph showing results of x-ray diffraction analysis of hafnium oxide films, which were formed without using silane gas and then heated at respective temperatures;

FIG. 7 is a graph showing results of x-ray diffraction analysis of hafnium silicate films, which were formed by using disilane gas, annealed in ammonia gas atmosphere, and then heated at respective temperatures;

FIG. 8 is a graph showing results of x-ray diffraction analysis of hafnium silicate films, which were formed by using monosilane gas, annealed in ammonia gas atmosphere, and then heated at respective temperatures; and

FIG. 9 is a graph showing the voltage-capacity characteristic of a MOS capacitor structure composed of an N-type silicon substrate, a hafnium silicate film, a silicon nitride film and a P-type gate electrode, in comparison with the voltage-capacity characteristic of a MOS capacitor structure without the silicon nitride film.

### DETAILED DESCRIPTION OF PREFERRED EMBODIMENTS

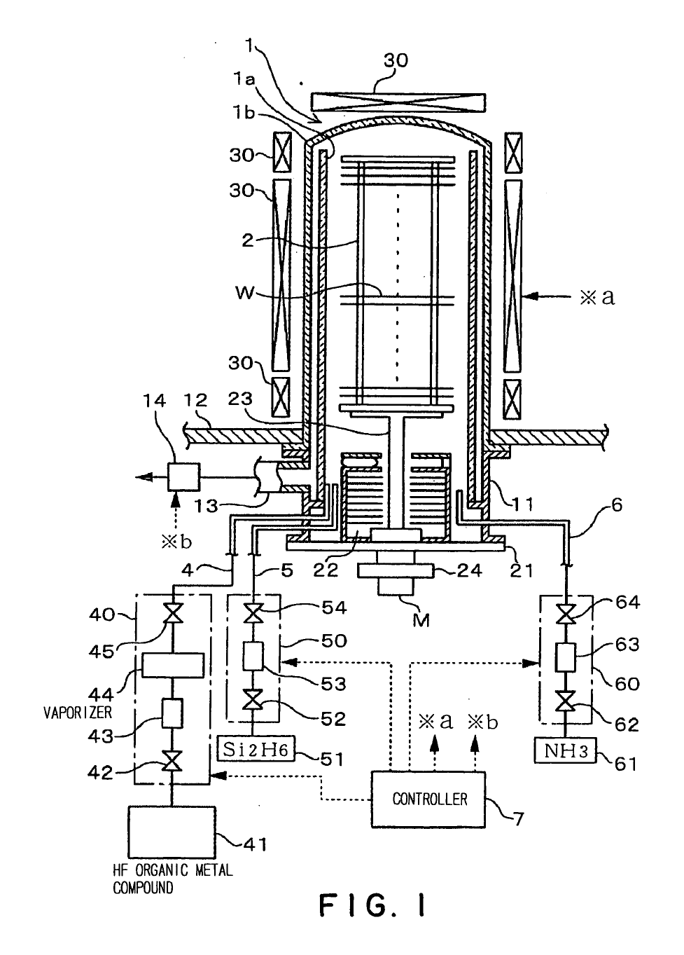

A film forming apparatus that performs a film forming method will be described with reference to FIG. 1. FIG. 1 shows the structure of a batch-type, low-pressure CVD apparatus, which is a vertical heat treatment apparatus. In FIG. 1, the reference number 1 depicts a reaction tube or a reaction vessel of a double tube structure including an inner tube 1a and an outer tube 1b both made of quartz. A cylindrical manifold 11 made of a metal is disposed on a lower part of the reaction tube 1. The upper end of the inner tube 1a is opened, while the lower end of the inner tube 1a is supported by an inner projection of the manifold 11. The upper end of the outer tube 1b is closed, while the lower end of the outer tube 1b is hermetically connected to the upper end of the manifold 11. The reference number 12 depicts a base plate.

FIG. 1 shows a state in which plural wafers W to be subjected to a film forming process are loaded in the reaction tube 1. In the reaction tube 1, a wafer boat 2 (i.e., holder) made of quartz supports the plural wafers W (i.e., process objects) horizontally at vertical intervals. Typically, the wafer boat 2 holds twenty-five product wafers, and dummy wafers above and below the product wafers. The wafer boat 2 is held on a lid 21 through an area where a heat-retaining unit 22 made of quartz is disposed. The heat-retaining unit 22 is composed of a heat-insulation unit formed of quartz fins and a heater unit. A rotating shaft 23 passes through the center of the heat-retaining unit 22. The wafer boat 2 is rotated through the rotating shaft 23 by a motor M mounted on a boat elevator 24.

The lid 21 is mounted on the boat elevator 24, which loads and unloads the wafer boat 2 into and from the reaction tube 1. In its uppermost position, the lid 21 closes the lower end opening of the manifold 11.

The reaction tube 1 is surrounded by heaters 30 (i.e., a heating means), which may be formed of resistance heating wires. For example, the heater 30 may be composed of a flexible carbon wire made of twisted, thin, high-purity carbon fibers, and a transparent quartz tube enclosing the wire. In the illustrated embodiment, the heaters includes: a main heater covering a major part of the reaction tube 1; sub-heaters disposed above and below the main heater; and a top heater disposed on the ceiling of the reaction tube 1. The main heater, the sub-heaters, and the top heater are all indicated by the reference number 30. A not shown furnace body (cover) is disposed around the heaters 30.

A first gas supply pipe 4, a second gas supply pipe 5, and a third gas supply pipe 6 are connected to the circumference of the manifold 11. Gases can be supplied from the respective gas supply pipes 4, 5, and 6 into the inner tube 1a. A liquid source supplying source 41 that supplies a hafnium organic compound such as tetra-tertiary-butoxy hafnium (Hf[OC(CH₃)₃]₄), a valve 42, a liquid massflow controller 43, a vaporizer 44, and a valve 45 are disposed on the first gas supply pipe 4, in that order from the upstream side thereof. The liquid source supplying source 41 is a device configured to force a hafnium organic compound in a liquid state out of a tank storing the same, when a pressurized gas is supplied to the tank.

A disilane gas supplying source 51 that supplies disilane (Si₂H₆) gas or a silane-series gas, a valve 52, a massflow controller 53 serving as a flow-rate adjusting device, and a valve 54 are disposed on the second gas supply pipe 5, in that order from the upstream side thereof. An ammonia gas supplying source 61 that supplies ammonia (NH₃) gas, a valve 62, a massflow controller 63 serving as a flow-rate adjusting device, and a valve 64 are disposed on the third gas supply pipe 6, in that order from the upstream side thereof. The devices for the gas-supplying operations including the valves, the flow controller, and the vaporizer, which are disposed on the gas supply pipes 4, 5 and 6 constitute first, second and third gas supplying means 40, 50 and 60, respectively.

An exhaust pipe 13 is connected to the manifold 11 to discharge an atmosphere in a space between the inner tube 1a and the outer tube 1b. A vacuum pump, not shown, is connected to the exhaust pipe 13 via a pressure adjusting device 14.

The low-pressure CVD apparatus is provided with a controller 7 consisting of a computer. The controller 7 runs a treatment program, reads out instructions of a process recipe stored in a not-shown memory, and controls process conditions based on the recipe. The controller 7 outputs control signals for controlling the heaters 30, the pressure adjusting unit 14, and the first to third gas supplying means 40, 50, and 60.

Next, a first embodiment of the film-forming method, which is carried out by using the above low-pressure CVD apparatus, is described below. At first, the wafer boat 2 holding the semiconductor wafers W is raised by the boat elevator 24, and is loaded into the reaction tube 1. This state is shown in FIG. 1. A silicon film of N-type or P-type has been already deposited on the surface of each silicon wafer W. After the wafer boat 2 is loaded into the reaction tube 1, the lower end opening of the manifold 11 is closed by the lid 21. Then, the temperature in the reaction tube 1 is raised by the heater 30 to a predetermined process temperature (e.g., 200° C. to 300° C.), while the reaction tube 1 is evacuated by the vacuum pump 15 through the exhaust pipe 13 to a predetermined degree of vacuum.

After the interior of the reaction vessel is stabilized at the predetermined process temperature, tetra-tertiary-butoxy hafnium in a liquid state is fed from the liquid source supplying source 41, the flow rate thereof being adjusted by the liquid massflow controller 43 to a predetermined flow rate (e.g., 0.02 sccm to 1 sccm). Thereafter, the liquid tetra-tertiary-butoxy hafnium is fed to the vaporizer 44, is vaporized by the vaporizer 44, and the vapor is supplied into the reaction tube 1. Disilane gas whose flow rate is adjusted by the massflow controller 53 to a predetermined flow rate (e.g., 50 sccm to 1,000 sccm) is supplied into the reaction tube 1 through the second gas-supplying pipe 5. The pressure in the reaction tube 1 is adjusted by the pressure adjusting device 14 to a predetermined reduced pressure, for example, 26.6 Pa to 133 Pa (0.2 Torr to 1.0 Torr). Thus, the tetra-tertiary-butoxy hafnium and the disilane gas are thermally decomposed in the reaction tube 1, and a film containing hafnium, oxygen, and silicon, i.e., a hafnium silicate film is deposited on the wafer W. During the film-deposition process, the wafer boat 2 is rotated by the motor M.

After the film-deposition process is performed for a predetermined period of time, the supply of the film-deposition gases is stopped, the gases remaining in the reaction tube 1 are purged with an inert gas, and the wafer boat 2 is unloaded from the reaction tube 1. Following thereto, the unloaded wafers W are subjected to a film-deposition process by another film-forming apparatus, so as to deposit a polysilicon film serving as a gate electrode on each wafer.

A hafnium silicate film, which contains silicon as well as hafnium and oxygen, is deposited on each wafer by the above film-deposition process. As silicon suppresses crystallization of hafnium oxide, the obtained hafnium compound film (i.e., a high dielectric constant film) has a higher crystallization temperature, which will be clearly seen from the examples described later. Therefore, during manufacture of a MOSFET, for example, if a polysilicon film on such a hafnium silicate film is subjected to an annealing treatment at a high temperature, a crystallization of the hafnium silicate film can be suppressed. As a result, the leak current of the gate oxide film formed of the hafnium silicate film can be reduced, so that a MOSFET having excellent electric properties can be obtained.

In this embodiment, since disilane gas having a lower decomposition temperature is employed, silicon content in the hafnium compound film can be increased, resulting in an improved crystallization suppression effect. In addition, since disilane gas contains no carbon, the increase in carbon content in the hafnium compound film, which may occur where a silicon organic compound is used as a silicon source, can be prevented.

Although a disilane gas is used as a silane-series gas in this embodiment, it is possible to use a monosilane (SiH₄) gas or another gas expressed as SiₙH₍₂ₙ₊₂₎.

Next, a second embodiment of the film-forming method according to the present invention will be described. In the second embodiment, a hafnium compound film is subjected to an annealing treatment (i.e., a modification process) by supplying thereto a compound of nitrogen and hydrogen, such as ammonia (NH₃) gas, while the hafnium compound film is heated.

The annealing treatment may be successively performed after the deposition of the hafnium silicate film described in connection with the first embodiment. In this case, the wafers W (i.e., process objects) can be consecutively processed in the reaction tube 1, without being unloaded from the reaction tube 1, namely, without being exposed to the air atmosphere.

After the deposition of the hafnium silicate film is completed, the gases remaining in the reaction tube 1 is completely discharged by a vacuum pump (not shown). Subsequently, the interior of the reaction tube 1 is heated to a predetermined temperature (e.g., 500° C. to 900° C.). Then, the pressure in the reaction tube 1 is adjusted to a predetermined pressure of, for example, 2.66×10² Pa to 1.60×10⁴ Pa (2 Torr to 120 Torr), while ammonia gas is supplied into the reaction tube 1 at a predetermined flow rate (e.g., 2 slm) through the third gas supply pipe 6. The annealing treatment is carried out for a predetermined period of time (e.g., 5 minutes to 60 minutes).

A series of these process steps is performed under the control of the controller 7, which reads out a predetermined recipe so as to control the respective devices and units.

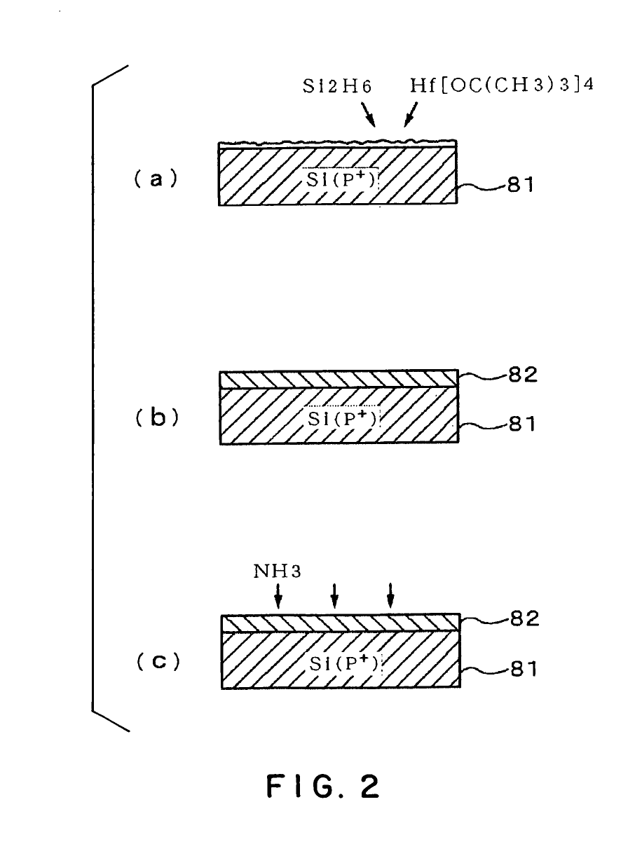

FIG. 2 shows schematic illustrations for explaining a series of process steps. FIGS. 2(a) and 2(b) show a step of depositing a hafnium silicate film 82 on a P-type silicon film (silicon layer) 81, by using tetra-tertiary-butoxy hafnium and disilane gas (corresponding to the first embodiment). FIG. 2(c) shows the hafnium silicate film 82 being subjected to the annealing treatment (corresponding to the second embodiment). The annealing of the hafnium compound film, such as a hafnium silicate film, by using ammonia results in increase in the crystallization temperature of the film by about 50° C., which will be clearly seen from the examples described later. Although the reason is not clear, it is considered that the annealing treatment forms Si—N bonds and Hf—N bonds which suppress phase separation between HfO₂ and SiO₂, so that the crystallization of the film can be suppressed.

In the second embodiment, the annealing treatment of a hafnium silicate film is described. However, the annealing treatment by using ammonia can effectively suppress the crystallization of other oxygen-containing hafnium compound films such as a hafnium oxide film which is obtained through thermal decomposition of tetra-tertiary-butoxy hafnium. The deposition of the hafnium compound film and the annealing treatment by using ammonia may be performed by separate apparatuses.

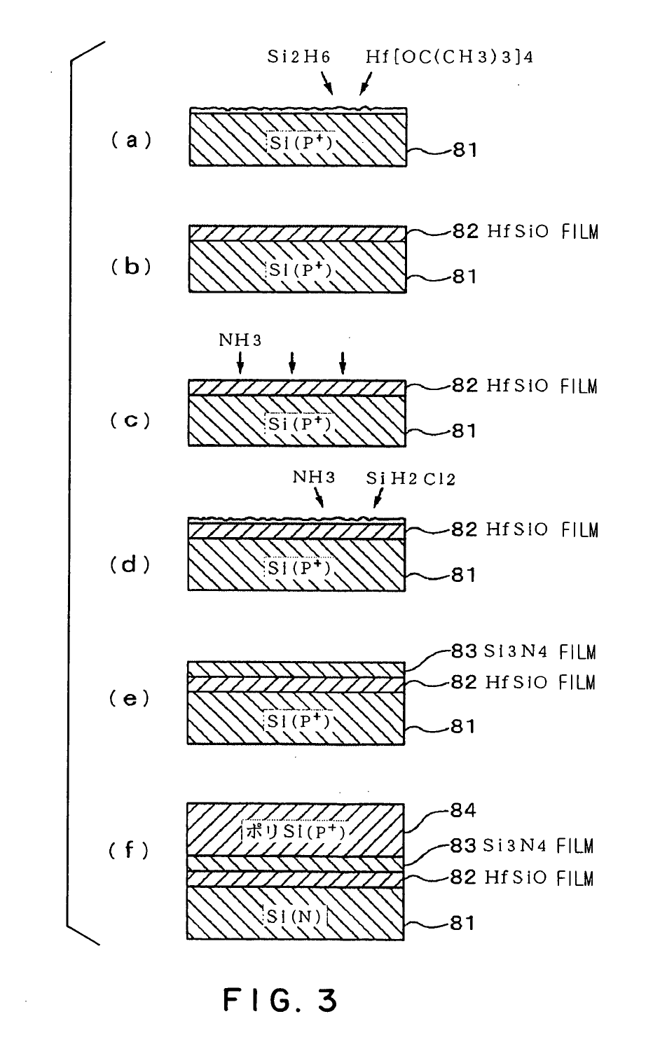

Next, a third embodiment of the film-forming method according to the present invention will be described with reference to FIG. 3.

Similar to the first and second embodiments, steps shown in FIG. 3(a) to (c) are carried out at first. After the step shown in FIG. 3(c) is completed, a silicon nitride (Si₃N₄) film 83 is deposited on the hafnium silicate film 82 having been annealed by using ammonia, by using ammonia gas and dichlorosilane (SiH₂Cl₂) gas, which step is shown in FIGS. 3(d) and 3(e). Film-deposition conditions of the silicon nitride film in a typical embodiment are as follows: the temperature (process temperature) in the reaction tube is 650° C.; the pressure (process pressure) in the reaction tube is 0.15 Torr; the flow rate of ammonia gas is 150 sccm; and the flow rate of dichlorosilane gas is 30 sccm. Under these conditions, the silicon nitride film having a thickness of about 0.35 nm is deposited. As shown in FIG. 3f, a polysilicon film 84 serving as a gate electrode is deposited on the silicon nitride film 83, according to a method known to those skilled in the art.

In the embodiment shown in FIG. 3, the silicon film 81 is N-type, and the polysilicon film 84 is P-type. This is because, when evaluating electric properties of a stacked structure by applying thereto a voltage, the polysilicon film 84 must be P-type. However, in the embodiment shown in FIG. 3, the silicon film 81 may be P-type, and the polysilicon film 84 may be N-type.

In the gate electrode structure manufactured in accordance with the above process steps, the flat band voltage (Vfb) shift, which will occur when a voltage is applied between a gate electrode (polysilicon film 84) and the silicon film 81, can be greatly reduced, as compared with the case in which the polysilicon film 84 is directly stacked on the hafnium silicate film 82, which will be clearly seen from the examples described later. The reason is considered as follows: When a polysilicon film is deposited directly on a hafnium silicate film, a certain reaction product is formed in the interface between the films, which increases Vfb shift. However, when the silicon nitride film 83, which may serve as a barrier layer, is interposed between the hafnium silicate film and the polysilicon film, the reaction between the films is prevented.

The hafnium organic compound used as the liquid source in the above first to third embodiments is not limited to tetra-tertiary-butoxy hafnium, but may be hafnium alkoxide such as Hf(OC₃H₇)₄. The gas used for the annealing of a hafnium compound film is not limited to ammonia, but may be other compound gases of nitrogen and hydrogen, such as hydrazine (N₂H₂). The layer (layer indicated by the reference number 81 in FIGS. 2 and 3) on which a hafnium oxide film is deposited may be either a P-type or N-type silicon substrate, or a P-type or N-type silicon film deposited on a silicon substrate. The high dielectric constant film obtained by the present invention may be used not only for a gate oxide film but also a capacitive element used in a memory, for example. It goes without saying that a film-forming apparatus used for depositing a film is not limited to a batch-type, but may be a single substrate processing type.

Hereinbelow, advantages of the present invention are described on the basis of concrete examples.

### EXAMPLE 1

By using the vertical heat treatment apparatus shown in FIG. 1, hafnium silicate film having a thickness of about 15 nm were deposited on silicon substrates, each having a P-type silicon film previously deposited on a surface thereof. Film-deposition conditions were as follows:

Temperature in the reaction tube: 250° C.

Pressure in the reaction tube: 40 Pa

Flow rate of tetra-tertiary-butoxy hafnium: 0.25 sccm (liquid flow rate)

Flow rate of disilane gas: 1,000 sccm

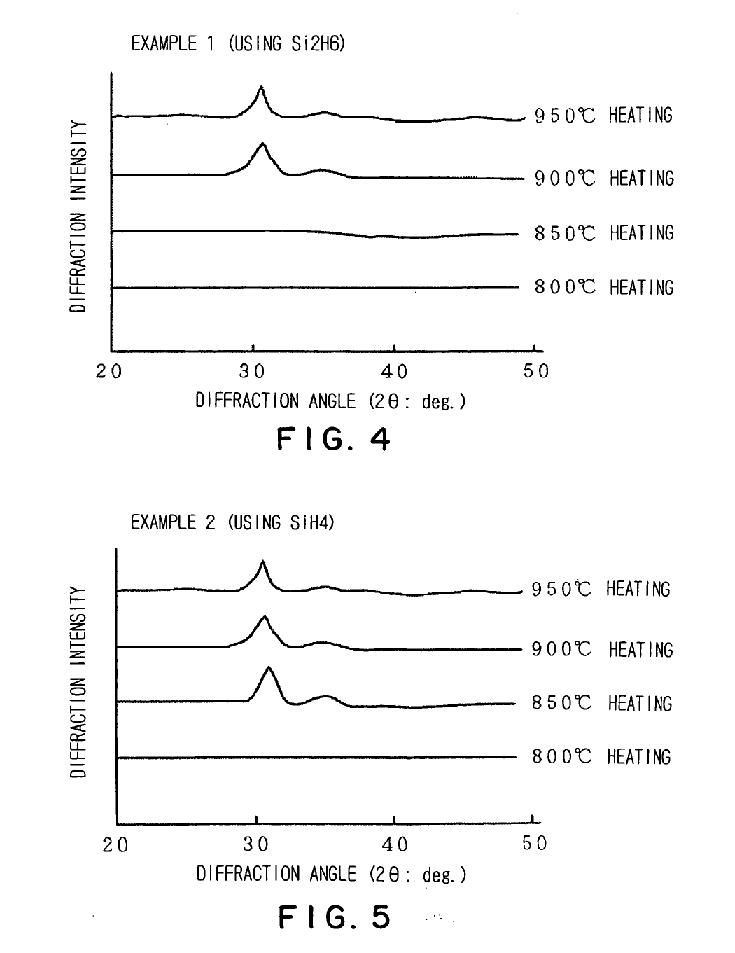

In order to examine the crystallization temperature of the hafnium silicate film deposited under the above conditions, the substrates were heated for one minute in an inert gas atmosphere, at different temperatures of 800° C., 850° C., 900° C. and 950° C., respectively. Then, x-ray diffraction analysis was conducted with respect to each of the heated hafnium silicate films. FIG. 4 shows the results. As is apparent from FIG. 4, in the substrate heated at 900° C., a (111) hafnium oxide peak appears at a position corresponding to the diffraction angle 2θ being about 30°. On the other hand, no peak appears in the substrate heated at 850° C. Thus, it was confirmed that the hafnium silicate film obtained under the above film-deposition conditions will not crystallize at 850° C.

### EXAMPLE 2

By using monosilane gas in place of disilane gas, hafnium silicate film having a thickness of about 15 nm were deposited on silicon substrates, each having a P-type silicon film previously deposited on a surface thereof. The flow rate of monosilane gas was 1,000 sccm, which is similar to that of the disilane gas in the Example 1. Other film-deposition conditions were the same as those in Example 1.

The thus obtained substrates were heated under the same conditions as those in Example 1, and then x-ray diffraction analysis were conducted. FIG. 5 shows the results. As is apparent from FIG. 5, a peak appears in the substrate heated at 850° C., while no peak appears in the substrate heated at 800° C. Thus, it was confirmed that the hafnium silicate film obtained under the film-deposition conditions of Example 2 will not crystallize at 800° C.

Although the hafnium silicate film deposited by using monosilane gas shows a sufficiently high crystallization temperature, which, however, is lower than that of the hafnium silicate film deposited by using disilane gas. The reason is considered as follows: Since the decomposition temperature of disilane gas is lower than that of monosilane gas, an amount of silicon taken into the hafnium silicate film deposited by using disilane gas is greater than that taken into the hafnium silicate film deposited by using monosilane gas. Thus, the film deposited by disilane gas has a larger silicon content (i.e., relative proportion of silicon with respect to hafnium) than that of the film deposited by using monosilane gas.

### Comparative Example 1

By using the same apparatus as used in Examples 1 and 2, hafnium oxide films having a thickness of 15 nm were deposited on silicon substrates, each having a P-type silicon film previously deposited on a surface thereof. Film-deposition conditions were as follows:

Temperature in the reaction tube: 250° C.

Pressure in the reaction tube: 40 Pa

Flow rate of tetra-tertiary-butoxy hafnium: 0.1 sccm (liquid flow rate)

Flow rate of oxygen gas: 1 slm

In Comparative Example 1, silane gas was not used for the film-deposition treatment.

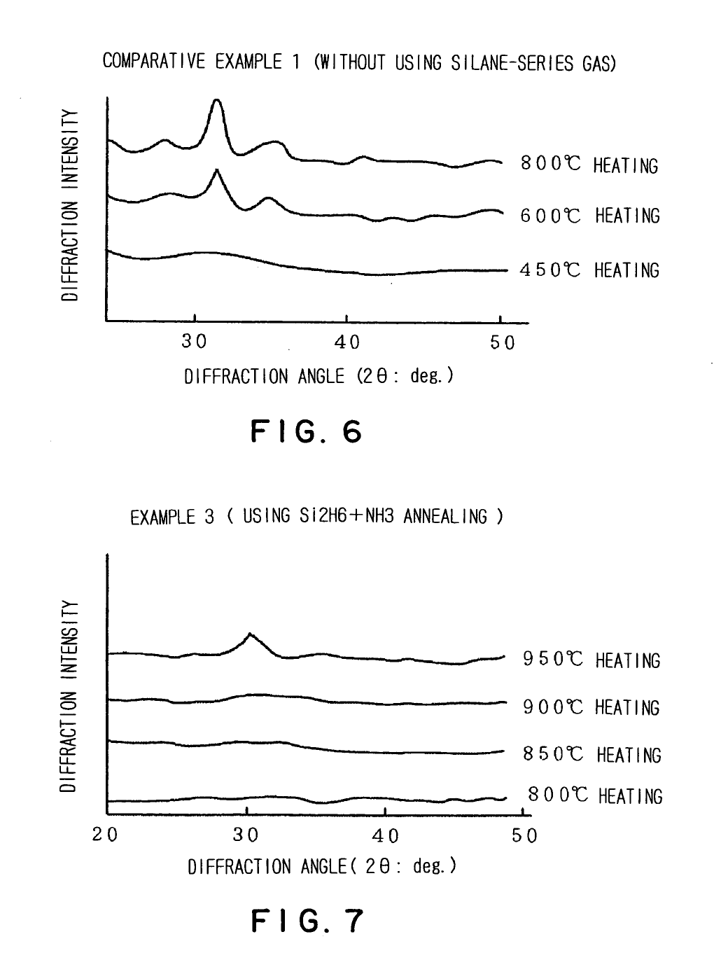

The substrates subjected to the above film-deposition process were heated for one minute in an inert gas atmosphere, at different temperatures of 450° C., 600° C., and 800° C., respectively. Then, x-ray diffraction analysis was conducted for each of the heated hafnium oxide films. FIG. 6 shows the results. As is apparent from FIG. 6, in the substrate heated at 450° C., the (111) hafnium oxide peak does not appear at a position corresponding to diffraction angle 2θ being about 30 degree. On the other hand, such a peak appears in the substrate heated at 600° C. That is, the hafnium compound film obtained under the film-deposition conditions of Comparative Example 1 will crystallize at 600° C., which crystallization temperature is lower than those of the hafnium compound films obtained under the film-deposition conditions of Examples 1 and 2. Thus, it was confirmed that a crystallization temperature of a hafnium compound film rises by using monosilane gas or disilane gas as a raw material gas.

### EXAMPLE 3

Under the same film-deposition conditions as those in Example 1 (a disilane gas was used), hafnium silicate films having a thickness of 12.63 nm were deposited on P-type silicon substrates. Then, the film was subjected to annealing in an ammonia gas atmosphere by using a vertical heat treatment apparatus which was different from the apparatus used for depositing the hafnium silicate films. Annealing conditions were as follows:

Temperature in the reaction tube: 600° C. to 900° C.

Pressure in the reaction tube: 2.66×10² Pa (2 Torr)

Flow rate of ammonia gas: 2 slm

Annealing time: 30 minutes

The annealed substrates were heated under the same conditions as those in Example 1, and x-ray diffraction analysis was similarly conducted with respect to the films on a surface of each substrate. FIG. 7 shows the results. As is apparent from FIG. 7, a peak appears in the substrate heated at 950° C., while no peak appears in the substrate heated at 900° C. Thus, it was confirmed that the hafnium silicate film obtained under the film-deposition conditions and the annealing conditions of Example 3 is not crystallize at 900° C. On the contrary, the hafnium silicate film obtained under the film-deposition condition of Example 1 (without annealing), the film crystallized at 900° C. Accordingly, it was confirmed that annealing treatment by using ammonia raises the crystallization temperature of a hafnium silicate film.

Under the same film-deposition conditions as those in Example 1, hafnium silicate films having a thickness of 12.63 nm was deposited on N-type silicon substrates. Then, the hafnium silicate films were annealed under the same annealing conditions as those in Example 3. Thereafter, a polysilicon film was deposited on each of the hafnium silicate films, and boron was implanted in the polysilicon film to form a gate electrode, so that a MOS capacitor structure was manufactured. Another MOS capacitor structure was manufactured in the same manner as above, except that the hafnium silicate films were not subjected to annealing treatment. By applying a voltage between the gate electrode and the N-type silicon film of each of the MOS capacitor structures, a capacity therebetween was measured. Then, the electric film thickness of each of the hafnium silicate films was calculated based on the measured capacity.

The electric film thickness of the not annealed hafnium silicate film was 1.6 nm, while the electric film thickness of the annealed hafnium silicate film was 1.2 nm. Thus, it was confirmed that the annealing treatment in an ammonia atmosphere reduces the electric film thickness of a hafnium compound film, in other words, increases a relative dielectric constant thereof.

### EXAMPLE 4

Under the same film-deposition conditions as those in Example 2 (a monosilane gas was used), hafnium silicate films having a film thickness of 12.63 nm were deposited on P-type silicon substrates. Then, the films were subjected to annealing in an ammonia gas atmosphere, under the same annealing conditions as those in Example 3.

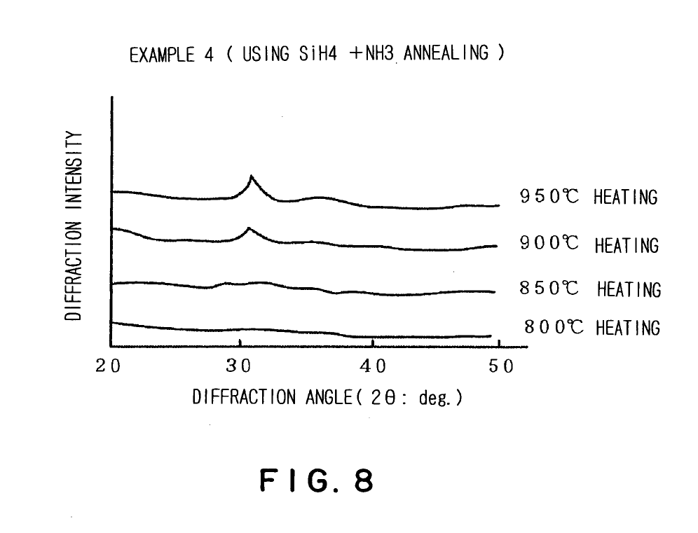

Thereafter, the substrates each having the hafnium silicate film were heated for one minute in an inert gas atmosphere, at different temperatures of 800° C., 850° C., 900° C., and 950° C., respectively. Then, x-ray diffraction analysis were conducted with respect to each of the heated hafnium silicate films. FIG. 8 shows the results.

As is apparent from the results, a peak appears in the substrate heated at 900° C., while no peak appears in the substrate heated at 850° C. Thus, it was confirmed that hafnium silicate film obtained in Example 4 was not crystallize at 850° C.

In view of the results of Example 2 (without annealing treatment), the hafnium silicate film crystallized at 850° C. Thus, it was confirmed that even when monosilane gas is used for depositing a hafnium silicate film, an annealing treatment by using ammonia rises the crystallization temperature of the hafnium silicate film.

### EXAMPLE 5

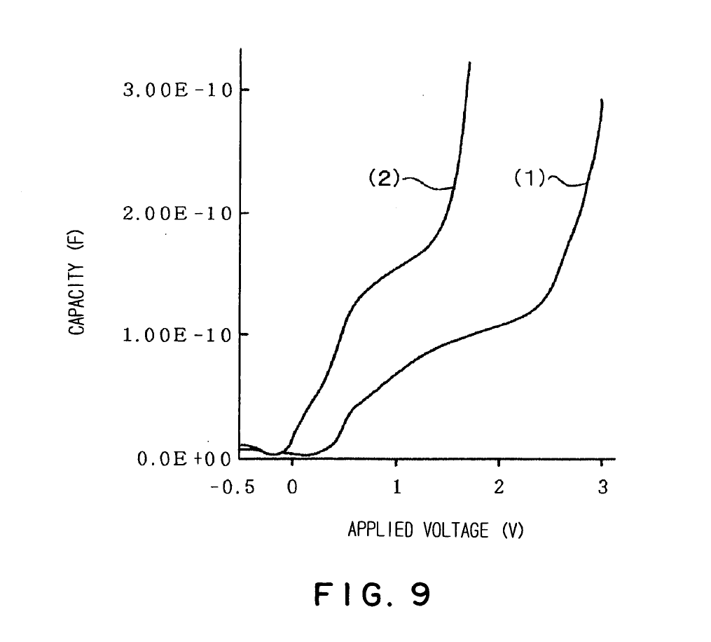

Under the same film-deposition conditions and annealing conditions as those in Example 3, a hafnium silicate film was deposited by using disilane gas, and then the film was subjected to annealing in an ammonia atmosphere. Thereafter, a silicon nitride film was deposited on the hafnium silicate film by a low-pressure CVD process by using dichlorosilane gas and an ammonia gas. After the annealing treatment by using ammonia, thicknesses of the respective films were measured. That is, the thickness of the hafnium silicate film was 2 nm to 3 nm, and the thickness of the silicon nitride film was 0.5 nm to 1.5 nm. Further, a polysilicon film serving as a gate electrode was deposited on the silicon nitride film, so that a MOS capacitor structure was manufactured. By applying a voltage between the gate electrode and the P-type silicon substrate, a relationship between the applied voltage and the capacity was investigated. FIG. 9 shows the result, which is indicated by the curve (1).

### Comparative Example 3

A thin-film transistor structure was manufactured, which had the same structure as that of Example 5, except for the absence of a silicon nitride film. The thickness of the hafnium silicate film of Comparative Example 3 was substantially the same as the sum of the thicknesses of the hafnium silicate film and the silicon nitride film in Example 5. The same test as above was conducted with respect to the thus obtained MOS capacitor structure. FIG. 9 shows the result, which is indicated by the curve (2).

Upon comparison of the results of Example 5 and Comparative Example 3, it was confirmed that, when a gate capacitive film is made of a stack consisting of a hafnium silicate film and a silicon nitride film deposited on a hafnium silicate film, electric properties of the gate capacitive film can be further improved.

1. A film forming method comprising:
reacting a hafnium organic compound and a silane-series gas in a reaction vessel, thereby depositing a hafnium silicate film on a substrate.

2. The film forming method according to claim 1, wherein
a heated atmosphere is established in an interior of the reaction vessel, and the hafnium organic compound is supplied into the reaction vessel in a vapor state.

3. The film forming method according to claim 1, wherein the silane-series gas comprises monosilane gas and/or disilane gas.

4. A film forming method comprising:
depositing a hafnium compound film containing hafnium and oxygen on a substrate; and
annealing the hafnium compound film, obtained by the depositing, in an atmosphere of a compound gas of nitrogen and hydrogen.

5. The film forming method according to claim 4, wherein the compound gas of nitrogen and hydrogen is ammonia gas.

6. The film forming method according to claim 4 further comprising:
depositing a silicon nitride film after the annealing of the hafnium compound film.

7. The film forming method according to claim 4, wherein the hafnium compound film is a hafnium silicate film deposited by reacting a hafnium organic compound and a silane-series gas.

8. A film forming apparatus comprising:
a reaction vessel into which a substrate is loaded;
a heating mechanism that heats an atmosphere in the reaction vessel;
a first gas-supplying means for supplying a vapor of a hafnium organic compound into the reaction vessel;
a second gas-supplying means for supplying a silane-series gas into the reaction vessel; and
a controller that controls the heating mechanism and the first and second gas-supplying means to deposit a hafnium silicate film on a substrate by reacting the hafnium organic compound and the silane-series gas in the reaction vessel.

9. The film forming method according to claim 2, wherein the silane-series gas comprises monosilane gas and/or disilane gas.

10. The film forming method according to claim 5 further comprising:
depositing a silicon nitride film after the annealing of the hafnium compound film.

11. The film forming method according to claim 5, wherein the hafnium compound film is a hafnium silicate film deposited by reacting a hafnium organic compound and a silane-series gas.

12. The film forming method according to claim 6, wherein the hafnium compound film is a hafnium silicate film deposited by reacting a hafnium organic compound and a silane-series gas.

13. The film forming method according to claim 10, wherein the hafnium compound film is a hafnium silicate film deposited by reacting a hafnium organic compound and a silane-series gas.
